(19) United States
(12) Patent Application Publication
(10) Pub. No.: US 2015/0258584 A1
(43) Pub. Date: Sep. 17, 2015

(54) SEPARATION AND REGENERATION APPARATUS AND SUBSTRATE PROCESSING APPARATUS

(71) Applicant: Tokyo Electron Limited, Tokyo (JP)

(72) Inventors: Kazuyuki Mitsuoka, Yamanashi (JP); Hiroki Ohno, Yamanashi (JP); Takehiko Orii, Yamanashi (JP); Takayuki Toshima, Kumamoto (JP)

(21) Appl. No.: 14/644,319

(22) Filed: Mar. 11, 2015

(30) Foreign Application Priority Data
Mar. 13, 2014 (JP) 2014-050870
Jan. 27, 2015 (JP) 2015-013479

(51) Int. Cl. B08B 3/14; H01L 21/02; H01L 21/67; B01D 3/00

(52) U.S. Cl. CPC B08B 3/14; B01D 3/00; H01L 21/02101; H01L 21/6704

(57) ABSTRACT

Disclosed is a separation and regeneration apparatus which includes a buffer tank configured to generate a mixed liquid which includes a first fluorine-containing organic solvent having a first boiling point, and a second fluorine-containing organic solvent having a second boiling point higher than the first boiling point; a distillation tank configured to heat the mixed liquid up to a temperature between the first boiling point and the second boiling point so as to separate the mixed liquid into the first fluorine-containing organic solvent in a gas state and the second fluorine-containing organic solvent in a liquid state; a first tank configured to liquefy and store the first fluorine-containing organic solvent in the gas state which is sent from the distillation tank; and a second tank configured to store the second fluorine-containing organic solvent in the liquid state which is sent from the distillation tank.

### CROSS-REFERENCE TO RELATED APPLICATIONS

This application is based on and claims priority from Japanese Patent Application Nos. 2014-050870 and 2015-013479, filed on Mar. 13, 2014 and Jan. 27, 2015, respectively, with the Japan Patent Office, the disclosure of which is incorporated herein in its entirety by reference.

### TECHNICAL FIELD

The present disclosure relates to a separation and regeneration apparatus and a substrate processing apparatus used to remove a liquid attached to the surface of a substrate by using a high-pressure fluid in a supercritical state or a subcritical state.

### BACKGROUND

In a fabricating process of a semiconductor device in which a lamination structure of an integrated circuit is formed on a surface of a semiconductor wafer (hereinafter, referred to as a “wafer”) which is a substrate, a liquid processing process is provided to process the wafer surface using a liquid, in which for example, minute dust or a natural oxide film on the wafer surface is removed with a cleaning liquid such as, for example, a chemical liquid.

However, with high integration of the semiconductor device, when, for example, the liquid attached to the surface of the wafer is removed in the liquid processing process, a phenomenon so-called a pattern collapse becomes problematic. The pattern collapse refers to a phenomenon in which, when the liquid remaining on the wafer surface is dried, the liquid remaining at left and right sides of, for example, a convex (that is, inside of a concave) of an unevenness forming a pattern is unevenly dried, and then a balance of surface tensions that draw the convex from side to side is lost, and thus, the convex collapses in a direction in which the liquid remains in a large amount.

As a technique for removing the liquid attached to the wafer surface while suppressing occurrence of the pattern collapse, a method using a fluid in a supercritical state or a subcritical state (hereinafter, the states are integrally referred to as a “high-pressure state”) has been known. The fluid (high-pressure fluid) in the high-pressure state is lower in viscosity and higher in capability of extracting the liquid than the liquid. In addition, no interface exists between the high-pressure fluid and the liquid or gas which is in an equilibrium state to the high-pressure fluid. Therefore, when the liquid attached to the wafer surface is substituted with the high-pressure fluid and thereafter, the state of the high-pressure fluid is changed to a gas state, the liquid may be dried without being influenced by the surface tension.

For example, in terms of high replaceability between the liquid and the high-pressure fluid and suppression of inflow of moisture in the liquid processing, Japanese Patent Laid-Open Publication No. 2011-187570 uses hydrofluoro ether (HFE) which is a fluorine-containing organic solvent (described as “fluorine compound” in Japanese Patent Laid-Open Publication No. 2011-187570) for both the dry prevention liquid and the high-pressure fluid. Further, the fluorine-containing organic solvent is suitable for the dry prevention liquid in terms of its flame-retardancy.

Meanwhile, the fluorine-containing organic solvent such as, for example, HFE, hydrofluoro carbon (HFC), perfluoro carbon (PFC), or perfluoro ether (PEE) is more expensive than, for example, isopropyl alcohol (IPA) and a volatile loss during wafer conveyance causes an increase in an operation cost. As a result, after the fluorine-containing organic solvent is used as the dry prevention liquid or the high-pressure fluid, when a mixed liquid of the fluorine containing organic solvent is stored and is used through separation and regeneration, the operation cost may be reduced.

### SUMMARY

The present disclosure provides a separation and regeneration apparatus including: a mixed liquid generating unit configured to generate a mixed liquid which includes a first fluorine-containing organic solvent having a first boiling point, and a second fluorine-containing organic solvent having a second boiling point higher than the first boiling point; a distillation tank including a heater configured to heat the mixed liquid up to a temperature between the first boiling point and the second boiling point, the distillation tank being configured to separate the mixed liquid into the first fluorine-containing organic solvent in a gas state and the second fluorine-containing organic solvent in a liquid state; a first tank configured to liquefy and store the first fluorine-containing organic solvent in the gas state which is sent from the distillation tank; and a second tank configured to store the second fluorine-containing organic solvent in the liquid state which is sent from the distillation tank, in which the distillation tank separates the mixed liquid into a liquid including the first fluorine-containing organic solvent in a large amount and a liquid including the second fluorine-containing organic solvent in a large amount in a separation ratio corresponding to a mixing ratio of the mixed liquid in the mixed liquid generating unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a horizontal plan view of a liquid processing apparatus.

FIG. 2 is a vertical side view of a liquid processing unit provided in the liquid processing apparatus.

FIG. 3 is a configuration diagram of a supercritical processing unit provided in the liquid processing apparatus.

FIG. 4 is an exterior perspective view of a processing container of the supercritical processing unit.

FIG. 5 is a schematic systematic diagram illustrating a separation and regeneration apparatus according to an exemplary embodiment.

FIG. 6 is a diagram illustrating an operation sequence of the exemplary embodiment.

FIG. 7 is a schematic systematic diagram illustrating an operation of the exemplary embodiment.

FIG. 8 is a view illustrating the availability of HFE7300 and FC43.

FIG. 9 is a view illustrating a separation and regeneration apparatus as a comparative example.

FIG. 10 is a schematic systematic diagram illustrating a separation and regeneration apparatus according to a modified example of the exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure was made in consideration of the problems described above and an object of the present disclosure is to provide a separation and regeneration apparatus and a substrate processing apparatus in which a fluorine-containing organic solvent used for removing a liquid attached to the surface of a wafer is used through separation and regeneration, and thus a reduction of an operation cost is achieved.

According to an aspect of the present disclosure, a separation and regeneration apparatus includes: a mixed liquid generating unit configured to generate a mixed liquid which includes a first fluorine-containing organic solvent having a first boiling point, and a second fluorine-containing organic solvent having a second boiling point higher than the first boiling point; a distillation tank including a heater configured to heat the mixed liquid up to a temperature between the first boiling point and the second boiling point, the distillation tank being configured to separate the mixed liquid into the first fluorine-containing organic solvent in a gas state and the second fluorine-containing organic solvent in a liquid state; a first tank configured to liquefy and store the first fluorine-containing organic solvent in the gas state which is sent from the distillation tank; and a second tank configured to store the second fluorine-containing organic solvent in the liquid state which is sent from the distillation tank. The distillation tank separates the mixed liquid into a liquid including the first fluorine-containing organic solvent in a large amount and a liquid including the second fluorine-containing organic solvent in a large amount in a separation ratio corresponding to a mixing ratio of the mixed liquid in the mixed liquid generating unit.

The separation and regeneration apparatus further includes a liquid processing unit configured to supply the first fluorine-containing organic solvent, and the second fluorine-containing organic solvent to a processing target object to perform a liquid processing.

In the separation and regeneration apparatus, a buffer tank is provided between the liquid processing unit and the distillation tank to constitute the mixed liquid generating unit.

In the separation and regeneration apparatus, the liquid processing unit constitutes the mixed liquid generating unit.

In the separation and regeneration apparatus, a first supply line is provided between the first tank and the liquid processing unit to supply the first fluorine-containing organic solvent, and a second supply line is provided between the second tank and the liquid processing unit to supply the second fluorine-containing organic solvent.

In the separation and regeneration apparatus, a first concentration meter is provided in the first supply line to measure a concentration of the first fluorine-containing organic solvent, and a second concentration meter is provided in the second supply line to measure a concentration of the second fluorine-containing organic solvent.

In the separation and regeneration apparatus, a first new liquid supply line is provided in the first tank to supply a new first fluorine-containing organic solvent, and a second new liquid supply line is provided in the second tank to supply a new second fluorine-containing organic solvent.

In the separation and regeneration apparatus, the mixed liquid generating unit is constituted by a mixed drainage liquid tank, and a stirring mechanism is provided in the mixed drainage liquid tank to stir the mixed liquid.

In the separation and regeneration apparatus, the mixed liquid generating unit is constituted by a mixed drainage liquid tank, and a cover is provided in at least one tank of the mixed drainage liquid tank, the first tank, and the second tank, the cover floating on a liquid surface to cover the liquid surface.

In the separation and regeneration apparatus, a preheater is provided between the mixed liquid generating unit and the distillation tank to preheat the mixed liquid.

According to another aspect of the present disclosure, a substrate processing apparatus includes: a liquid processing unit configured to supply a first fluorine-containing organic solvent having a first boiling point and a second fluorine-containing organic solvent having a second boiling point higher than the first boiling point to a processing target object to perform a liquid processing; a supercritical processing unit configured to bring a liquid of fluorine-containing organic solvent attached to the processing target object after the liquid processing into contact with a supercritical fluid of a fluorine-containing organic solvent to remove the liquid; and a substrate conveyance unit configured to convey the processing target object which has been subjected to the liquid processing in the liquid processing unit to the supercritical processing unit. The separation and regeneration apparatus described above is included in the liquid processing unit.

According to the present exemplary embodiment, the fluorine-containing organic solvent, which has been used for removing the liquid attached to the surface of the wafer, is used through separation and regeneration, and thus a reduction of an operation cost is achieved.

### Exemplary Embodiment of the Present Disclosure

<Substrate Processing Apparatus>

First, a substrate processing apparatus embedded with a separation and regeneration apparatus according to the present disclosure will be described. As one example of the substrate processing apparatus, a liquid processing apparatus 1 will be described, which includes a liquid processing unit 2 configured to perform a liquid processing by supplying various processing liquids to a wafer W (a processing target object) which is a substrate and a supercritical processing unit (high-pressure fluid processing unit) 3 configured to remove a dry prevention liquid, which is attached on the wafer W after the liquid processing, by bringing the dry prevention liquid into contact with a supercritical fluid (high-pressure fluid).

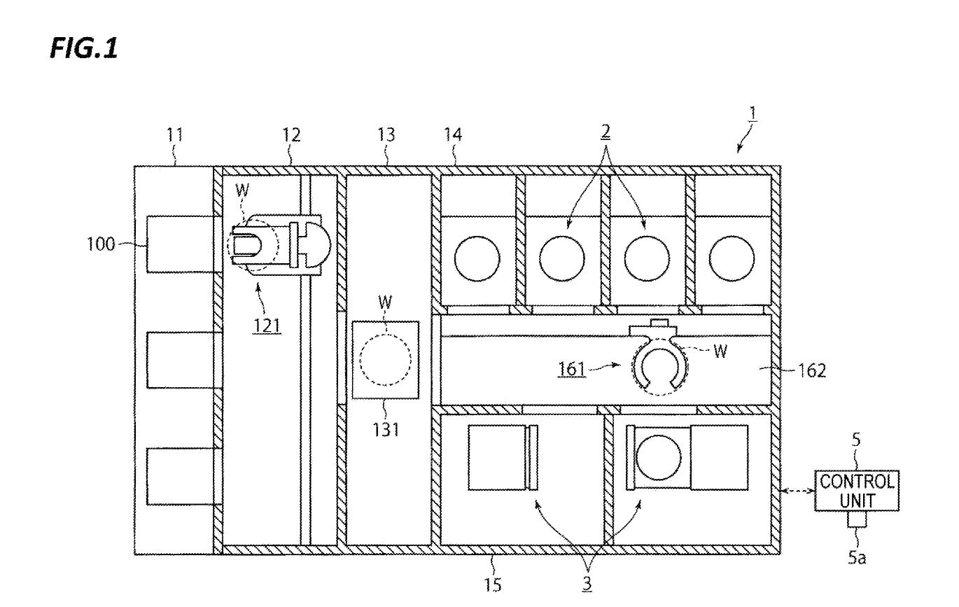

FIG. 1 is a horizontal plan view illustrating an overall configuration of the liquid processing apparatus 1. A left side of the drawing is set as a front side. In the liquid processing apparatus 1, a FOUP 100 is placed in a disposition unit 11. For example, a plurality of wafers W having a diameter of 300 mm accommodated in the FOUP 100 is delivered to/from a liquid processing section 14 and a supercritical processing section 15 at a latter stage through a carry-in/out section 12 and a delivery section 13, and is sequentially carried into the liquid processing unit 2 and the supercritical processing unit 3 so that a liquid processing or a processing of removing the dry prevention liquid is performed. In the drawing, reference numeral 121 represents a first conveyance mechanism that conveys the wafer W between the FOUP 100 and the delivery section 13, and reference numeral 131 is a delivery shelf serving as a buffer in which the wafer W conveyed between the carry-in/out section 12 and the liquid processing section 14, and the supercritical processing section 15 is temporarily placed.

The liquid processing section 14 and the supercritical processing section 15 are provided across a conveyance space 162 of the wafer W. The conveyance space 162 extends in a forward-backward direction from an opening between the delivery section 13 and the conveyance space 162. For example, four liquid processing units 2 are disposed along the conveyance space 162 in the liquid processing section 14 formed at a left side of the conveyance space 162 when viewed from the front side. Meanwhile, for example, two supercritical processing units 3 are disposed along the conveyance space 162 in the supercritical processing section 15 provided at a right side of the conveyance space 162.

The wafers W are conveyed among the liquid processing units 2, the supercritical processing units 3, and the delivery section 13 by a second conveyance mechanism 161 disposed on the conveyance space 162. The second conveyance mechanism 161 corresponds to a substrate conveyance unit. Herein, the number of the liquid processing units 2 or the supercritical processing units 3 disposed in the liquid processing section 14 or the supercritical processing section 15 is appropriately selected according to, for example, the number of wafers W processed per unit time or a difference in processing time between the liquid processing unit 2 and the supercritical processing unit 3, and an optimal layout is selected according to, for example, the number of the liquid processing units 2 or the supercritical processing units 3 that are disposed.

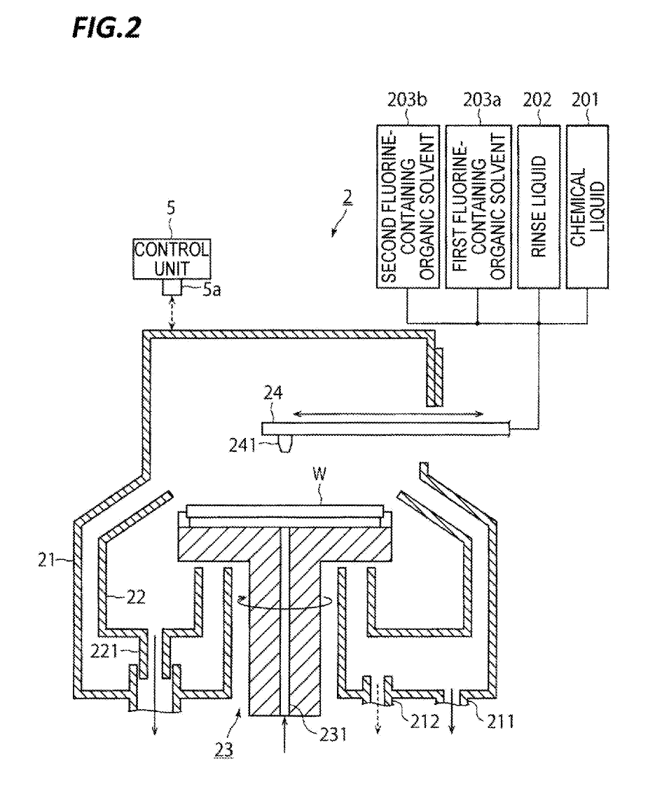

The liquid processing unit 2 is constituted by, for example, the single wafer-type liquid processing unit 2 that cleans the wafers W one by one by spin cleaning, and as illustrated in the vertical side view of FIG. 2, includes an outer chamber 21 that forms a processing space, a wafer holding mechanism 23 disposed in the outer chamber 21 and configured to rotate the wafer W around a vertical axis while substantially horizontally holding the wafer W, an inner cup 22 disposed to surround the wafer holding mechanism 23 from a side circumference and configured to receive a liquid scattered from the wafer W, and a nozzle arm 24 configured to move between a position above the wafer W and a position retreated from the position above the wafer W and having a nozzle 241 provided at a distal end thereof.

A processing liquid supplying unit 201 configured to supply various chemical liquids or a rinse liquid supplying unit 202 configured to supply a rinse liquid, and a first fluorine-containing organic solvent supplying unit 203a (first organic solvent supplying unit) configured to supply a first fluorine-containing organic solvent which is the dry prevention liquid to the surface of the wafer W, and a second fluorine-containing organic solvent supplying unit 203b (second organic solvent supplying unit) configured to supply a second fluorine-containing organic solvent are connected to the nozzle 241. As for the first and second fluorine-containing organic solvents, different solvents from a fluorine-containing organic solvent used for a supercritical processing to be described below are used and further, solvents having a predetermined relationship in terms of the boiling point or threshold temperature are employed as the first fluorine-containing organic solvent, the second fluorine-containing organic solvent and the supercritical processing fluorine-containing organic solvent, but a detailed description thereof will be described below.

A chemical liquid supply path 231 is formed even in the wafer holding mechanism 23 and a rear surface of the wafer W may be cleaned by the chemical liquid and the rinse liquid supplied from the chemical liquid supply path 231. An exhaust port 212 for exhausting an internal atmosphere or liquid discharge ports 221 and 211 for discharging the liquid scattered from the wafer W are formed on the bottom of the outer chamber 21 or the inner cup 22.

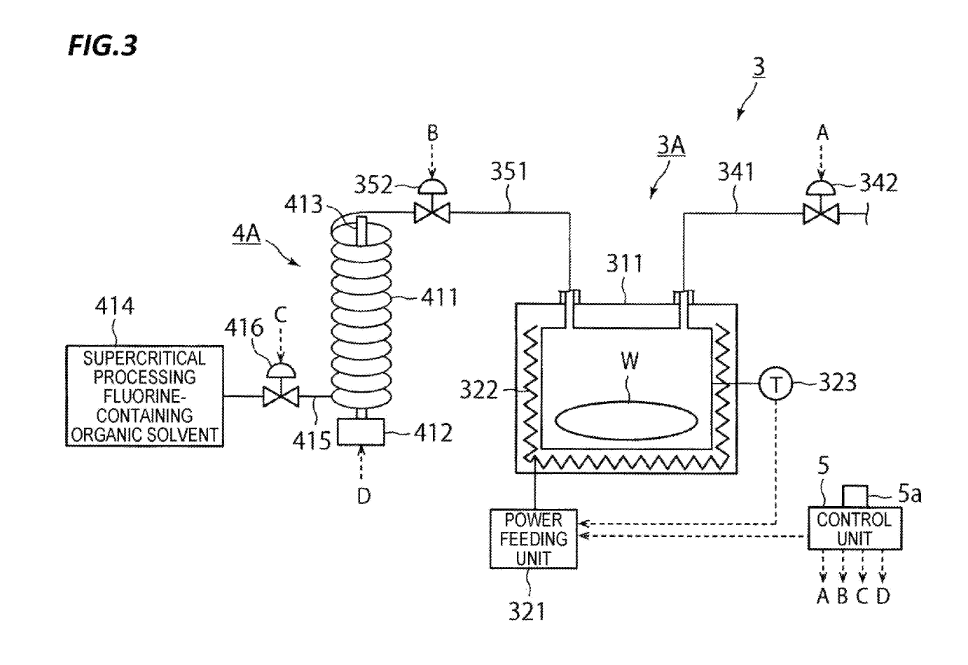

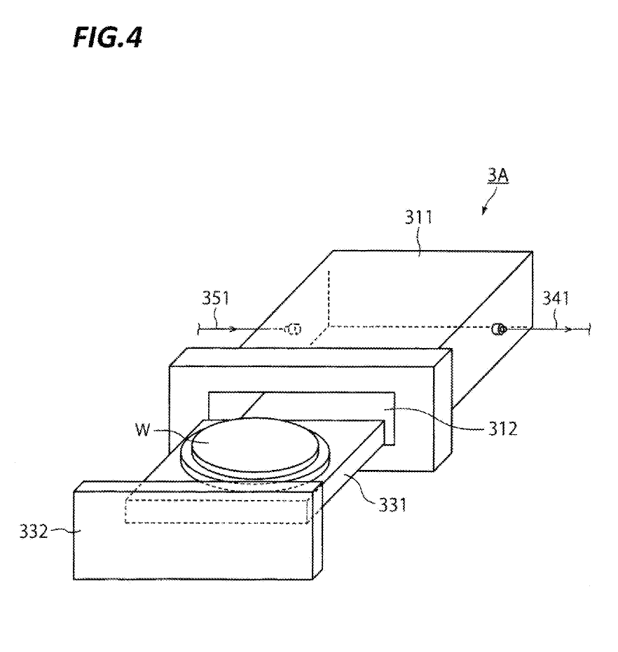

The first fluorine-containing organic solvent for the dry prevention and the second fluorine-containing organic solvent are supplied to the wafer W which has been subjected to a liquid processing in the liquid processing unit 2 and the wafer W is conveyed to the supercritical processing unit 3 by the second conveyance mechanism 161 with the surface of the wafer W being covered with the second fluorine-containing organic solvent. In the supercritical processing unit 3, the wafer W comes in contact with a supercritical fluid of the supercritical processing fluorine-containing organic solvent so that the second fluorine-containing organic solvent is removed and the wafer W is dried. Hereinafter, a configuration of the supercritical processing unit 3 will be described with reference to FIGS. 3 and 4.

The supercritical processing unit 3 includes a processing container 3A in which the dry prevention liquid (second fluorine-containing organic solvent) attached to the surface of the wafer W is removed, and a supercritical fluid supplying unit (supercritical processing organic solvent supplying unit) 4A configured to supply the supercritical fluid of the supercritical processing fluorine-containing organic solvent to the processing container 3A.

As illustrated in FIG. 4, the processing container 3A includes a case type container body 311 formed with an opening 312 for carry-in/out of the wafer W, a wafer tray 331 capable of holding the wafer W to be processed in a transverse direction, and a cover member 332 configured to support the wafer tray 331 and seal the opening 312 when the wafer W is carried into the container body 311.

The container body 311 is, for example, a container having a processing space with a volume of approximately 200 cm³ to 10000 cm³, which is capable of accommodating the wafer W having a diameter of 300 mm. A supercritical fluid supply line 351 for supplying the supercritical fluid into the processing container 3A and a discharge line (discharge unit) 341 for discharging the fluid in the processing container 3A are connected to the top of the container body 311. An opening/closing valve 342 is interposed in the discharge line 341. Further, a pressing mechanism (not illustrated) configured to seal the processing space by pushing the cover member 332 toward the container body 311 against internal pressure caused by a high-pressure processing fluid supplied into the processing space is provided in the processing container 3A.

For example, a heater 322 which is a heating unit constituted by, for example, a resistance heating element, and a temperature detecting unit 323 including, for example, a thermocouple for detecting a temperature in the processing container 3A are provided in the container body 311. The temperature in the processing container 3A is heated to a predetermined temperature by heating the container body 311 and thus, the wafer W within the processing container 3A may be heated. The heater 322 may change a caloric value by changing a power supplied from a power feeding unit 321 and control the temperature in the processing container 3A to a predetermined temperature based on the temperature detection result acquired from the temperature detecting unit 323.

The supercritical fluid supplying unit 4A is connected to an upstream side of the supercritical fluid supply line 351 interposed with an opening/closing valve 352. The supercritical fluid supplying unit 4A includes a spiral pipe 411 which is a pipe for preparing the supercritical fluid of the supercritical processing fluorine-containing organic solvent to be supplied to the processing container 3A, a supercritical processing fluorine-containing organic solvent supplying unit 414 configured to supply the liquid of the supercritical processing fluorine-containing organic solvent which is a raw material of the supercritical fluid to the spiral pipe 411, and a halogen lamp 413 configured to heat the spiral pipe 411 so that the supercritical processing fluorine-containing organic solvent within the spiral pipe 411 may be placed in a supercritical state.

The spiral pipe 411 is, for example, a cylindrical container formed by spirally winding a stainless pipe member in the longitudinal direction thereof and is painted with, for example, a black radiant heat absorption paint in order to easily absorb radiant heat supplied from the halogen lamp 413. The halogen lamp 413 is disposed spaced apart from an inner wall surface of the spiral pipe 411 along a cylindrical central axis of the spiral pipe 411. A power supply unit 412 is connected to a lower end of the halogen lamp 413, and the halogen lamp 413 emits heat by a power supplied from the power supply unit 412 so that the spiral pipe 411 is heated primarily by using the radiant heat. The power supply unit 412 is connected with a temperature detecting unit (not illustrated) provided in the spiral pipe 411 and increases or decreases the power supplied to the spiral pipe 411 based on a detection temperature to heat the inside of the spiral pipe 411 at a predetermined temperature.

Further, a pipe member extends from the lower end of the spiral pipe 411 to form a reception line 415 of the supercritical processing fluorine-containing organic solvent. The reception line 415 is connected to the supercritical processing fluorine-containing organic solvent supplying unit 414 through an opening/closing valve 416 having pressure resistance. The supercritical processing fluorine-containing organic solvent supplying unit 414 includes, for example, a tank configured to store the supercritical processing fluorine-containing organic solvent in a liquid state or a liquid feeding pump, a flow rate control mechanism.

The liquid processing apparatus 1 including the liquid processing unit 2 or the supercritical processing unit 3 configured as described above is connected to a control unit 5 as illustrated in FIGS. 1 to 3. The control unit 5 is constituted by a computer including a CPU (not illustrated) and a memory unit 5a. The memory unit 5a memorizes a program in which a group of steps (commands) on a control associated with operations of the liquid processing apparatus 1 is incorporated. That is, the operations include extracting the wafer W from the FOUP 100 and performing the liquid processing of the extracted wafer W in the liquid processing unit 2 and subsequently, drying the wafer W in the supercritical processing unit 3, and carrying the wafer W into the FOUP 100. The program is stored in memory media such as, for example, a hard disk, a compact disk, a magneto optical disk, and a memory card and then installed into the computer therefrom.

Next, descriptions will be made on the first fluorine-containing organic solvent and the second fluorine-containing organic solvent supplied to the surface of the wafer W in the liquid processing unit 2, and the supercritical processing fluorine-containing organic solvent supplied to the processing container 3A in the state of the supercritical fluid in order to remove the second fluorine-containing organic solvent from the surface of the wafer W. All of the first fluorine-containing organic solvent, the second fluorine-containing organic solvent, and the supercritical processing fluorine-containing organic solvent are fluorine-containing organic solvents including fluorine atoms in hydrocarbon molecules.

An example of a combination of the first fluorine-containing organic solvent, the second fluorine-containing organic solvent and the supercritical processing fluorine-containing organic solvent is illustrated in Table 1.

TABLE 1

| | | | | Boiling |
|---|---|---|---|---|
| | | | Class | Point |
| | Maker | Product Name | Name | (° C.) |
| First fluorine- | Asahi Garasu | AE-3000 | HFE | 56 |
| containing | Co., Ltd. | | | |
| organic | Asahi Garasu | AC-6000 | HFC | 115 |
| solvent | Co., Ltd. | | | |
| | Asahi Garasu | AC-2000 | HFC | 68 |
| | Co., Ltd. | | | |
| | Sumitomo 3M | Novec (registered | HFE | 61 |
| | Co., Ltd. | trademark) 7100 | | |
| | Sumitomo 3M | Novec (registered | HFE | 76 |
| | Co., Ltd. | trademark) 7200 | | |
| | Sumitomo 3M | Novec (registered | HFE | 98 |
| | Co., Ltd. | trademark) 7300 | | |
| | Sumitomo 3M | Novec (registered | HFE | 128 |
| | Co., Ltd. | trademark) 7500 | | |
| Second | Sumitomo 3M | Fluorinert (registered | PFC | 165 |
| fluorine- | Co., Ltd. | trademark) FC-40 | | |
| containing | Sumitomo 3M | Fluorinert (registered | PFC | 174 |
| organic | Co., Ltd. | trademark) FC-43 | | |
| solvent | Sumitomo 3M | Fluorinert (registered | PFC | 128 |
| | Co., Ltd. | trademark) FC-3283 | | |
| | Solvay Solexis | GALDEN (registered | PFE | 200 |
| | Co., Ltd. | trademark) HT200 | | |
| | Solvay Solexis | GALDEN (registered | PFE | 170 |
| | Co., Ltd. | trademark) | | |
| Supercritical | Sumitomo 3M | Fluorinert (registered | PFC | 56 |
| processing | Co., Ltd. | trademark) FC-72 | | |
| fluorine- | | | | |
| containing | | | | |
| organic | | | | |
| solvent | | | | |

Among class names of Table 1, hydrofluoro ether (HFE) is a fluorine-containing organic solvent acquired by replacing some hydrogen of hydrocarbon having an ether bond in a molecule with fluorine, and hydrofluoro carbon (HFC) is a fluorine-containing organic solvent acquired by replacing some hydrogen of hydrocarbon with fluorine. Further, perfluoro carbon (PFC) is a fluorine-containing organic solvent acquired by replacing all hydrogen of hydrocarbon with fluorine and perfluoro ether (PFE) is a fluorine-containing organic solvent acquired by replacing all hydrogen of hydrocarbon having an ether bond in the molecule with fluorine.

When one fluorine-containing organic solvent is selected as the supercritical processing fluorine-containing organic solvent among the fluorine-containing organic solvents, another fluorine-containing organic solvent which is higher in a boiling point (lower in vapor pressure) than the supercritical processing fluorine-containing organic solvent is selected as the second fluorine-containing organic solvent. As a result, compared with the case in which the supercritical processing fluorine-containing organic solvent is adopted as the dry prevention liquid, the amount of the fluorine-containing organic solvent volatilized from the surface of the wafer W may be reduced while the wafer W is conveyed to the supercritical processing unit 3 from the liquid processing unit 2.

More appropriately, a boiling point of the first fluorine-containing organic solvent may be about 100° C. (e.g., 98° C.), and a boiling point of the second fluorine-containing organic solvent may be 100° C. or higher (for example, 174° C.), which is higher than that of the first fluorine-containing organic solvent. Since the second fluorine-containing organic solvent having the boiling point of 100° C. or higher is smaller in a volatilization quantity during conveyance of the wafer W, the surface of the wafer W may be maintained in a wet state for approximately dozens of seconds to 10 minutes only by supplying a small amount of fluorine-containing organic solvent, that is, in a small amount of approximately 0.01 cc to 5 cc to a wafer W having a diameter of 300 mm or approximately 0.02 cc to 10 cc to a wafer W having a diameter of 450 mm For reference, IPA needs to be supplied in an amount of approximately 10 cc to 50 cc to maintain the surface of the wafer W in the wet state for the same time as above.

Further, when two kinds of fluorine-containing organic solvents are selected, high and low values of the boiling point correspond to high and low values of a supercritical temperature. Therefore, as for the supercritical processing fluorine-containing organic solvent used as the supercritical fluid, the fluorine-containing organic solvent which is lower in a boiling point than the second fluorine-containing organic solvent is selected so that a fluorine-containing organic solvent capable of forming the supercritical fluid at a low temperature may be used and the fluorine atoms may be prevented from being released due to decomposition of the fluorine-containing organic solvent.

<Separation and Regeneration Apparatus>

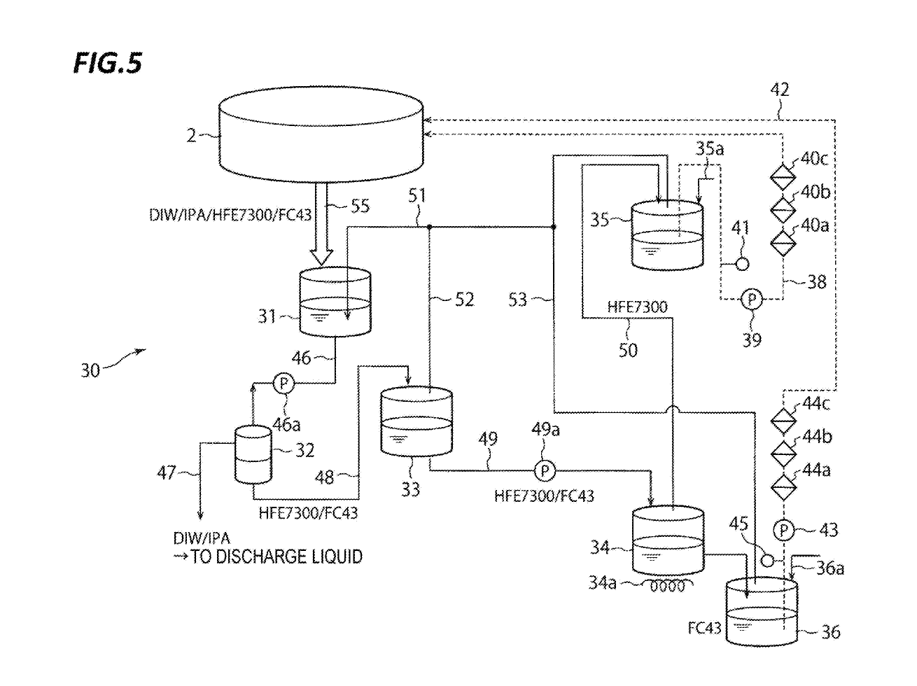

Next, descriptions will be made on the separation and regeneration apparatus according to the present exemplary embodiment, which is incorporated in the substrate processing apparatus, with reference to FIGS. 5 to 9.

As illustrated in FIGS. 5 to 9, a separation and regeneration apparatus 30 includes the above described liquid processing unit 2 configured to accommodate the wafer W, and supply the chemical liquids, the rise liquid, the first fluorine-containing organic solvent, and the second fluorine-containing organic solvent to the wafer W to perform a liquid processing, and a mixed drainage liquid tank 31 configured to store the drainage liquid from the liquid processing unit 2. In the mixed drainage liquid tank 31, the drainage liquid sent from the liquid processing unit 2 through a discharge line 55 is stored. The drainage liquid includes deionized water (DIW) which is a rinse liquid as described below, IPA, the first fluorine-containing organic solvent, and the second fluorine-containing organic solvent.

The drainage liquid is sent from the mixed drainage liquid tank 31 to an oil-water separator 32 through a supply line 46 attached with a pump 46a. Then, the drainage liquid is separated into oil and water by the oil-water separator 32, DIW and IPA are discharged to the outside through a discharge line 47, and the mixed liquid of the first fluorine-containing organic solvent and the second fluorine-containing organic solvent is sent to a buffer tank 33 through a supply line 48.

Then, the mixed liquid of the first fluorine-containing organic solvent and the second fluorine-containing organic solvent is sent from the buffer tank 33 to a distillation tank 34 through a supply line 49 attached with a pump 49a.

The distillation tank 34 separates a first fluorine-containing organic solvent (e.g., HFE7300) having a first boiling point (e.g., 98° C.) and a second fluorine-containing organic solvent (e.g., FC43) having a second boiling point (e.g., 174° C.) higher than the first boiling point in the mixed liquid to generate a gas type first fluorine-containing organic solvent, and a liquid type second fluorine-containing organic solvent. The distillation tank 34 includes a heater 34a configured to heat the mixed liquid, so that the mixed liquid is heated up to a temperature between the first boiling point (e.g., 98° C.) and the second boiling point (e.g., 174° C.), for example, in a range of 120° C. to 150° C. Meanwhile, the first boiling point and the second boiling point are not limited to boiling points at the atmospheric pressure. For example, when the internal pressure of the distillation tank 34 is increased, the boiling point is increased as known, and as a result, the heater 34a may have a temperature between the first boiling point and the second boiling point which are changed.

The gas type first fluorine-containing organic solvent separated in the distillation tank 34 is sent to a first tank 35 through a supply line 50, and is liquefied and stored in the first tank 35.

The liquid type second fluorine-containing organic solvent is sent from the distillation tank 34 to a second tank 36 to be stored.

The first fluorine-containing organic solvent within the first tank 35 is returned to the liquid processing unit 2 through a first supply line 38.

The first supply line 38 is attached with a pump 39, and with an organic matter removing filter 40a including activated carbon, an ion removing filter 40b including activated alumina, and a particle removing filter 40c. A first concentration meter 41 is provided in the first supply line 38.

A surplus pressure return line 51 is connected to the upper portion of the first tank 35 to return a surplus pressure within the first tank 35 to the mixed drainage liquid tank 31.

The second fluorine-containing organic solvent within the second tank 36 is returned to the liquid processing unit 2 through a second supply line 42.

The second supply line 42 is attached with a pump 43, and with an organic matter removing filter 44a including activated carbon, an ion removing filter 44b including activated alumina, and a particle removing filter 44c. A second concentration meter 45 is provided in the second supply line 42.

A surplus pressure return line 53 is connected to the upper portion of the second tank 36 to return a surplus pressure within the second tank 36 to the mixed drainage liquid tank 31. The surplus pressure return line 53 joins to the surplus pressure return line 51 to reach the mixed drainage liquid tank 31.

A first new supply line 35a and a second new supply line 36a are provided in the first tank 35 and the second tank 36 to supply a new first fluorine-containing organic solvent and a new second fluorine-containing organic solvent, respectively.

As for the first concentration meter 41 and the second concentration meter 45, a specific gravimeter that measures a change in specific gravity corresponding to a change in concentration or an optical measurer that measures a change in refractive index corresponding to the change in concentration may be used.

Further, components of the separation and regeneration apparatus 30, for example, the pumps 46a, 49a, 39, and 43 and the distillation tank 34 are driven and controlled by the control unit 5 having the memory unit 5a.

### <Operation of Exemplary Embodiment>

Next, an operation of the present exemplary embodiment as configured above will be described.

In the present exemplary embodiment, descriptions will be made on the operation in a case in which HFE7300 is used as the first fluorine-containing organic solvent, FC43 is used as the second fluorine-containing organic solvent, and FC72 is used as the supercritical processing fluorine-containing organic solvent.

First, the wafer W extracted from the FOUP 100 is carried into the liquid processing section 14 through the carry-in/out section 12 and the delivery section 13 and is delivered to the wafer holding mechanism 23 of the liquid processing unit 2. Continuously, various processing liquids are supplied to the surface of the wafer W which rotates to perform a liquid-processing.

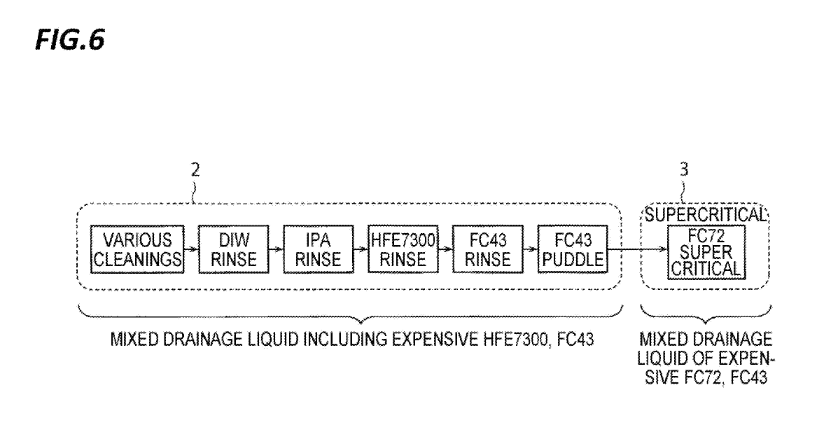

As illustrated in FIG. 6, in the liquid processing, for example, particles or organic pollutant substances are removed by an SC1 liquid (a mixed liquid of ammonia and hydrogen peroxide) which is an alkaline chemical liquid and thereafter, a rinse cleaning is performed by deionized water (DIW) which is a rinse liquid.

When the liquid processing or the rinse cleaning, which uses the chemical liquid, is completed, IPA is supplied from the rinse liquid supplying unit 202 to the surface of the rotating wafer W to replace DIW which remains on the top surface and the rear surface of the wafer W. When the liquid on the surface of the wafer W is sufficiently replaced with the IPA, the first fluorine-containing organic solvent (HFE7300) is supplied to the surface of the rotating wafer W from the first fluorine-containing organic solvent supplying unit 203a and thereafter, the rotation of the wafer W stops. Then, the wafer W is rotated, the second fluorine-containing organic solvent (FC43) is supplied to the surface of the rotating wafer W from the second fluorine-containing organic solvent supplying unit 203b and thereafter, and the rotation of the wafer W stops. The surface of the wafer W of which the rotation stops is covered with the second fluorine-containing organic solvent. In this case, since the IPA has high affinity with DIW and HFE7300, and HFE7300 has high affinity with IPA and FC43, DIW may be certainly replaced with IPA and next, IPA may be certainly replaced with HFE7300. Next, HFE7300 may be easily and certainly replaced with FC43.

The wafer W on which the liquid processing has been completed is carried out from the liquid processing unit 2 by the second conveyance mechanism 161 and conveyed to the supercritical processing unit 3. Since the fluorine-containing organic solvent having the high boiling point (the low vapor pressure) is used as the second fluorine-containing organic solvent, the amount of the fluorine-containing organic solvent volatilized from the surface of the wafer W during the conveyance may be reduced.

In a period of time before the wafer W is carried into the processing container 3A, the supercritical fluid supplying unit 4A feeds a predetermined amount of liquid of the supercritical processing fluorine-containing organic solvent from the supercritical processing fluorine-containing organic solvent supplying unit 414 by opening the opening/closing valve 416 and thereafter, seals the spiral pipe 411 by closing the opening/closing valves 352 and 416. In this case, the liquid of the supercritical processing fluorine-containing organic solvent stagnates at the lower side of the spiral pipe 411. A space is left at the upper side of the spiral pipe 411, in which the supercritical processing fluorine-containing organic solvent is expanded when being evaporated by heating.

Then, when the halogen lamp 413 emits heat by initiating a power feeding from the power supply unit 412 to the halogen lamp 413, the inside of the spiral pipe 411 is heated, and as a result, the supercritical processing fluorine-containing organic solvent is evaporated. Then, the temperature and pressure of the supercritical processing fluorine-containing organic solvent increase to reach a threshold temperature and a threshold pressure so that the supercritical processing fluorine-containing organic solvent becomes the supercritical fluid. The temperature and the pressure of the supercritical processing fluorine-containing organic solvent in the spiral pipe 411 rise up to a temperature and a pressure at which the threshold temperature and the threshold pressure may be maintained when the supercritical processing fluorine-containing organic solvent is supplied to the processing container 3A.

By this configuration, the wafer W of which the liquid processing has been completed and the surface is covered with the second fluorine-containing organic solvent is carried into the supercritical processing unit 3 that has been prepared to supply the supercritical fluid of the supercritical processing fluorine-containing organic solvent.

When the wafer W is carried into the processing container 3A and the cover member 332 is closed to seal the processing container 3A as illustrated in FIG. 3, the supercritical fluid of the supercritical processing fluorine-containing organic solvent is supplied from the supercritical fluid supplying unit 4A by opening the opening/closing valve 352 of the supercritical fluid supply line 351 before the second fluorine-containing organic solvent on the surface of the wafer W is dried.

When the supercritical fluid is supplied from the supercritical fluid supplying unit 4A and the inside of the processing container 3A is thus placed in a supercritical fluid atmosphere of the supercritical processing fluorine-containing organic solvent, the opening/closing valve 352 of the supercritical fluid supply line 351 is closed. The supercritical fluid supplying unit 4A turns off the halogen lamp 413, discharges the fluid in the spiral pipe 411 through a depressurization line (not illustrated), and prepares for receiving the supercritical processing fluorine-containing organic solvent in the liquid state from the supercritical processing fluorine-containing organic solvent supplying unit 414 in order to prepare for the subsequent supercritical fluid.

Meanwhile, the supply of the supercritical fluid from the outside to the processing container 3A stops and the inside of the processing container 3A is sealed while being filled with the supercritical fluid of the supercritical processing fluorine-containing organic solvent. In this case, when attention is focused on the surface of the wafer W in the processing container 3A, the supercritical fluid of the supercritical processing fluorine-containing organic solvent is in contact with the liquid of the second fluorine-containing organic solvent that enters a pattern.

When the contact state between the liquid of the second fluorine-containing organic solvent and the supercritical fluid is maintained, the second fluorine-containing organic solvent and the supercritical processing fluorine-containing organic solvent which are highly miscible are mixed with each other and the liquid in the pattern is replaced with the supercritical fluid. Finally, the liquid of the second fluorine-containing organic solvent is removed from the surface of the wafer W and an atmosphere of the supercritical fluid of a mixture of the second fluorine-containing organic solvent and the supercritical processing fluorine-containing organic solvent is formed around the pattern. In this case, since the liquid of the second fluorine-containing organic solvent may be removed at a comparatively low temperature close to the threshold temperature of the supercritical processing fluorine-containing organic solvent, the fluorine-containing organic solvent is hardly decomposed and the amount of generated hydrogen fluoride that causes damage to, for example, the pattern is also small.

By this configuration, when a time required for removing the liquid of the second fluorine-containing organic solvent from the surface of the wafer W has elapsed, the fluorine-containing organic solvent is discharged from the inside of the processing container 3A by opening the opening/closing valve 342 of the discharge line 341. In this case, for example, the amount of the heat supplied from the heater 322 is controlled so as to maintain the inside of the processing container 3A at a temperature equal to or greater than the threshold temperature of the supercritical processing fluorine-containing organic solvent. As a result, the mixed fluid may be discharged in the supercritical state or in the gas state without liquefying the second fluorine-containing organic solvent having the boiling point lower than the threshold temperature of the supercritical processing fluorine-containing organic solvent, and the occurrence of the pattern collapse may be prevented at the time of discharging the fluid.

When the processing by the supercritical fluid is terminated, the wafer W which is dried by removing the liquid is extracted by the second conveyance mechanism 161 and conveyed through a route opposite to that for carrying-in of the wafer W to be accommodated in the FOUP 100, and a series of processings on the wafer W is terminated. The aforementioned processing is continuously performed on the respective wafers W in the FOUP 100 in the liquid processing apparatus 1.

In the meantime, as illustrated in FIG. 5, a drainage liquid is sent from the liquid processing unit 2 into the mixed drainage liquid tank 31. The drainage liquid is stored in the mixed drainage liquid tank 31.

The drainage liquid includes DIW, IPA, the first fluorine-containing organic solvent (HFE7300), and the second fluorine-containing organic solvent (FC43). In the drainage liquid within the mixed drainage liquid tank 31, each of HFE7300 and FC43 is included in 15 cc per wafer W. Thus, a mixing ratio of HFE7300 and FC43 is 1:1.

Then, the drainage liquid is sent from the mixed drainage liquid tank 31 to the oil-water separator 32 through the supply line 46 by the pump 46a. Then, the drainage liquid is separated into oil and water in the oil-water separator 32, so that DIW and IPA are discharged to the outside through the discharge line 47, and the mixed liquid of the first fluorine-containing organic solvent and the second fluorine-containing organic solvent is sent to the buffer tank 33 through the supply line 48. In this case, the buffer tank 33 serves as a mixed liquid generating unit configured to generate a mixed liquid which includes the first fluorine-containing organic solvent and the second fluorine-containing organic solvent.

Then, the mixed liquid of the first fluorine-containing organic solvent and the second fluorine-containing organic solvent is sent from the buffer tank 33 to the distillation tank 34 through the supply line 49 by the pump 49a.

The distillation tank 34 separates the first fluorine-containing organic solvent having a first boiling point (e.g., 98° C.) and the second fluorine-containing organic solvent having a second boiling point (e.g., 174° C.) higher than the first boiling point in the mixed liquid through heating by the heater 34a to generate a gas type first fluorine-containing organic solvent, and a liquid type second fluorine-containing organic solvent. In this case, the mixed liquid has a temperature between the first boiling point (e.g., 98° C.) and the second boiling point (e.g., 174° C.), for example, in a range of 120° C. to 150° C. by the heater 34a at atmospheric pressure (1 atm).

The gas type first fluorine-containing organic solvent separated in the distillation tank 34 is sent to the first tank 35 through the supply line 50, and is liquefied and stored in the first tank 35.

The liquid type second fluorine-containing organic solvent is sent from the distillation tank 34 to the second tank 36 to be stored.

The first fluorine-containing organic solvent within the first tank 35 is returned to the liquid processing unit 2 through the first supply line 38 by the pump 39. Meanwhile, the first fluorine-containing organic solvent within the first tank 35 is purified by the organic matter removing filter 40a including activated carbon, the ion removing filter 40b including activated alumina, and the particle removing filter 40c provided in the first supply line 38. The concentration of the first fluorine-containing organic solvent is measured by the first concentration meter 41 provided in the first supply line 38. The surplus pressure within the first tank 35 is returned to the mixed drainage liquid tank 31 by the surplus pressure return line 51.

The second fluorine-containing organic solvent within the second tank 36 is returned to the liquid processing unit 2 through the second supply line 42 by the pump 43. Meanwhile, the fluorine-containing organic solvent within the second tank 36 is purified by the organic matter removing filter 44a including activated carbon, the ion removing filter 44b including activated alumina, and the particle removing filter 44c provided in the second supply line 42. The concentration of the second fluorine-containing organic solvent is measured by the second concentration meter 45 provided in the second supply line 42.

The surplus pressure within the second tank 36 is returned to the mixed drainage liquid tank 31 by the surplus pressure return line 53.

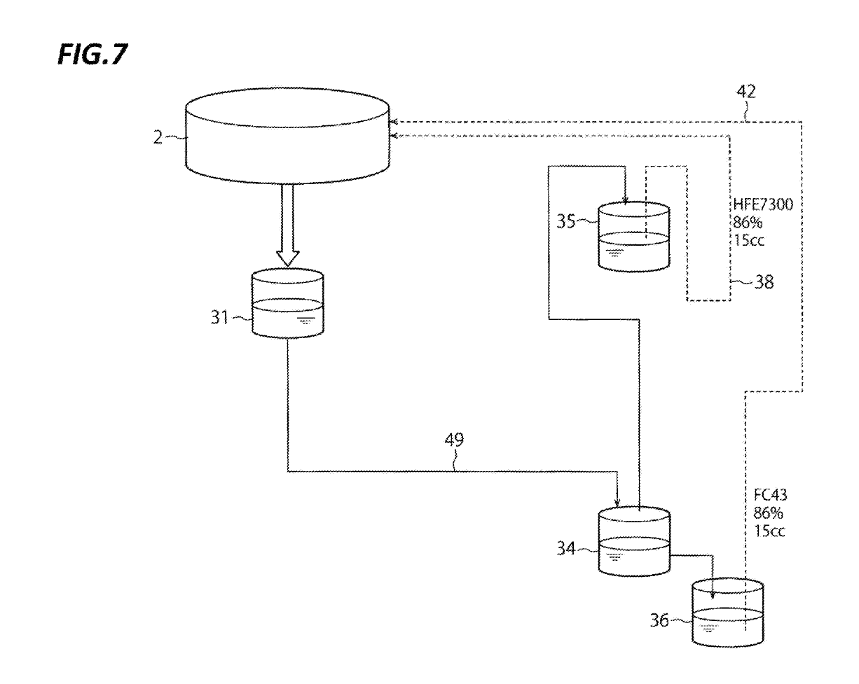

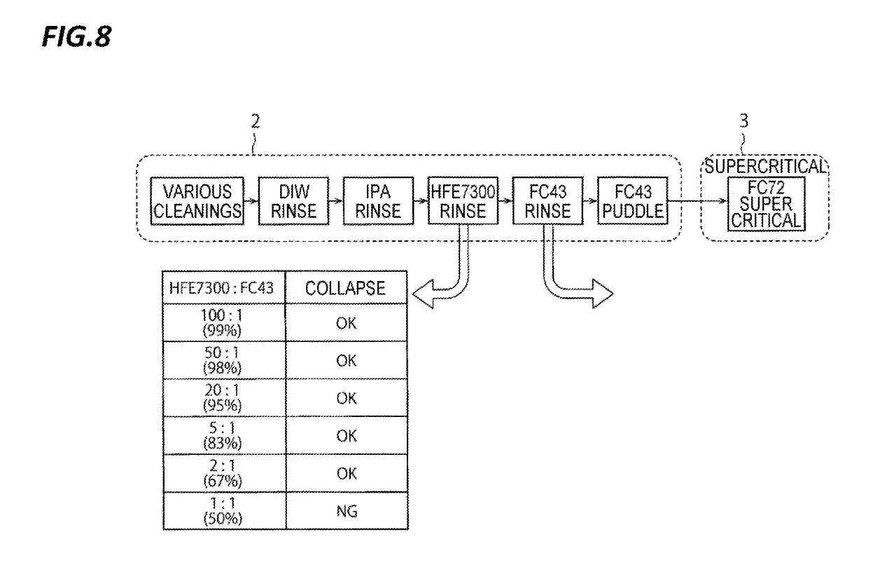

Hereinafter, descriptions will be made on a relationship between a mixing ratio of the mixed liquid including the first fluorine-containing organic solvent (HFE7300) and the second fluorine-containing organic solvent (FC43) in the buffer tank 33, and a separation ratio of the separation of the mixed liquid in the distillation tank 34 with reference to FIGS. 7 and 8.

As described above, in the drainage liquid within the mixed drainage liquid tank 31, each of HFE7300 and FC43 is included in 15 cc per wafer W. Thus, a mixing ratio of HFE7300 and FC43 is 1:1. Also, in the buffer tank 33, a mixing ratio of HFE7300 and FC43 is also 1:1.

Within the distillation tank 34, the mixed liquid is heated by the heater 34a to be separated into the gas type HFE7300 and the liquid type FC43. The separation ratio corresponds to the mixing ratio of the mixed liquid, that is, 1:1.

As illustrated in FIG. 7, within the distillation tank 34, the mixed liquid is separated into the gas type HFE7300 and the liquid type FC43 in a separation ratio of 1:1 to generate 15 cc of HFE7300 and 15 cc of FC43 per wafer W. In this case, when the purity of HFE7300 separated in the distillation tank 34 is, for example, 86%, the purity of FC43 separated in the distillation tank 34 is also 86% because the mixing ratio of HFE7300 and FC43 is 1:1.

Therefore, HFE7300 with purity of 86% is returned in an amount of 15 cc per wafer W to the liquid processing unit 2 from the first tank 35, and FC43 with purity of 86% is returned in an amount of 15 cc per wafer W to the liquid processing unit 2 from the second tank 36.

In this case, within the liquid processing unit 2, first, HFE7300 with purity of 86% is supplied as the first fluorine-containing organic solvent to the wafer W, and then, FC43 with purity of 86% is supplied as the second fluorine-containing organic solvent to the wafer W.

As illustrated in FIG. 8, when HFE7300 (the rest FC43) with purity of 86% is supplied to the wafer W, there is no problem at all because if the purity of HFE7300 is 67% or more, the pattern collapse does not occur. Then, when FC43 (the rest HFE7300) with purity of 86% is supplied to the wafer W, a sufficient puddle of FC43 may be formed on the wafer W because FC43 and HFE7300 are dissolved with high affinity.

When HFE7300 in an amount of 30 cc per wafer W, and FC43 in an amount of 15 cc per wafer W are mixed in a mixing ratio of 2:1 within the buffer tank 33, a separation ratio within the distillation tank 34 is also 2:1.

In this case, when the purity of HFE7300 separated within the distillation tank 34 is, for example, 90%, the purity of FC43 becomes 80%. Here, in the liquid processing unit 2, HFE7300 with purity of 90% is supplied in 30 cc to the wafer W, and then FC43 with purity of 80% is supplied in 15 cc to the wafer W. Since HFE7300 supplied to the wafer W has a purity of 90%, the pattern collapse does not occur. Then, when FC43 with purity of 80% is supplied to the wafer W, a sufficient puddle of FC43 may be formed on the wafer W because FC43 and HFE7300 are dissolved with high affinity.

In the present exemplary embodiment as described above, the separation ratio in the distillation tank 34 is determined according to the mixing ratio within the buffer tank 33. Thus, even if the purity of each of HFE7300 and FC43 separated in the distillation tank 34 is less than 100%, HFE7300 and FC43 may be returned to the liquid processing unit 2 so as to be supplied to the wafer W without any problems. In this case, the pattern on the wafer W is not collapsed, and HFE7300 and FC43 are dissolved with high affinity, and thus a sufficient puddle of FC43 may be formed on the wafer W.

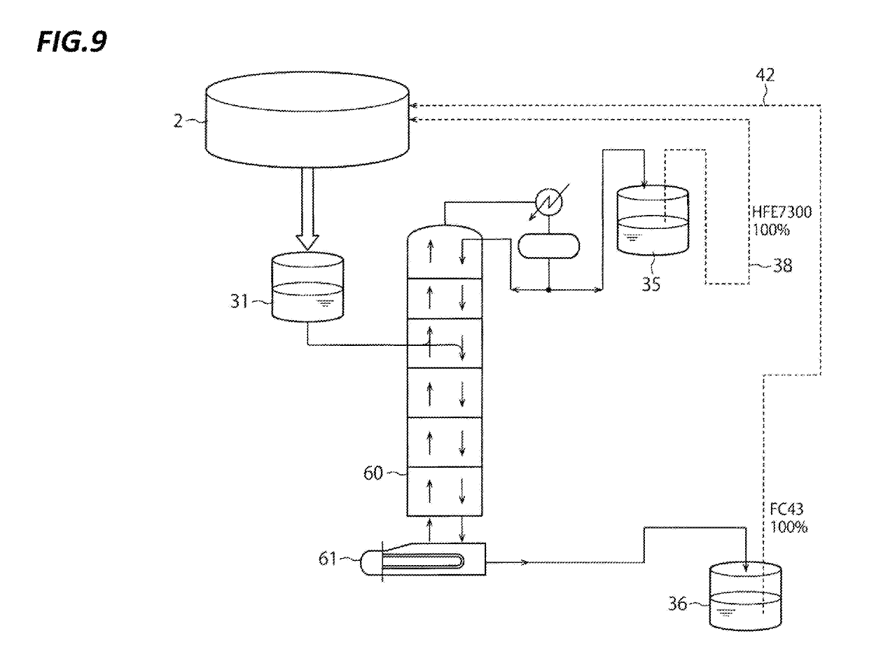

A separation and regeneration apparatus as a comparative example of the present exemplary embodiment is illustrated in FIG. 9. As illustrated in FIG. 9, when a rectifying column 60 in multi-stages and a reboiler 61 are provided, instead of the distillation tank 34 in a single stage, the mixed liquid of HFE7300 and FC43 sent from the mixed drainage liquid tank 31 to the rectifying column 60 may be separated into HFE7300 and FC43. In this case, after the separation, HFE7300 and FC43 may be stored with purity of 100% in the first tank 35 and the second tank 36, respectively. However, in order to provide the rectifying column 60 in multi-stages, the installation cost is increased, and further, it is necessary to take a large installation space.

In contrast, according to the present exemplary embodiment, since the distillation tank 34 in a single stage is used, a cost reduction may be achieved and an installation space may be reduced. Even if HFE7300 and FC43 generated in the distillation tank 34 are returned to the liquid processing unit 2, the pattern on the wafer W is not collapsed, and a sufficient puddle of FC43 may be formed on the wafer W.

In the above described exemplary embodiment, the buffer tank 33 serves as a mixed liquid generating unit, in which the drainage liquid is guided from the liquid processing unit 2 to the mixed drainage liquid tank 31 and the buffer tank 33 to generate a mixed liquid of HFE7300 and FC43 within the buffer tank 33, and then, the mixed liquid is sent to the distillation tank 34, but the present disclosure is not limited thereto. The mixed liquid of HFE7300 and FC43 generated in the liquid processing unit 2 may be directly sent to the distillation tank 34, while the liquid processing unit 2 serves as the mixed liquid generating unit.

<Another Application>

The present disclosure may be variously modified without being limited to the above described exemplary embodiment. For example, in the above described exemplary embodiment, in the liquid processing unit 2, the first fluorine-containing organic solvent is supplied to the wafer W, and then the second fluorine-containing organic solvent is supplied to the W, but the present disclosure is not limited thereto. In the liquid processing unit 2, after the second fluorine-containing organic solvent is supplied to the wafer W, the first fluorine-containing organic solvent may be supplied to the wafer W. The first fluorine-containing organic solvent and the second fluorine-containing organic solvent may be preferably dissolved with high affinity so that the amount of the fluorine-containing organic solvent volatilized from the surface of the wafer W may be reduced while the wafer W is conveyed to the supercritical processing unit 3 from the liquid processing unit 2.

In order to improve separation and regeneration of the used fluorine-containing organic solvents, the following three functions are added.

### MODIFIED EXAMPLE OF THE PRESENT DISCLOSURE

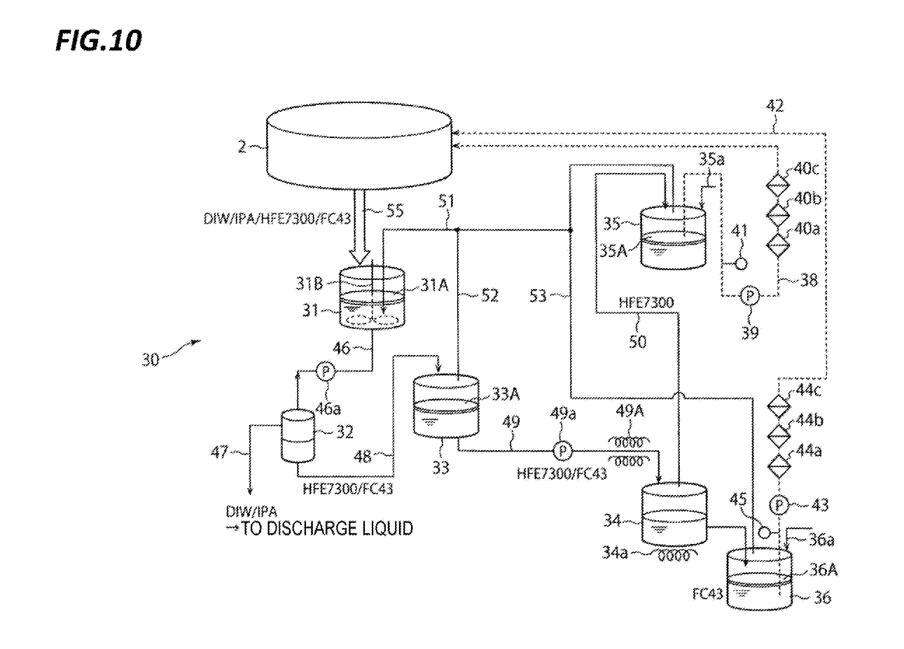

Hereinafter, the modified example of the present disclosure will be described with reference to FIG. 10.

In the modified example illustrated in FIG. 10, a stirring mechanism 31B is provided in the mixed drainage liquid tank 31, covers 31A, 33A, 35A, and 36A are provided in the mixed drainage liquid tank 31, the buffer tank 33, the first tank 35 and the second tank 36, and a preheater 49A is provided in the supply line 49. Other components are almost the same as those in the exemplary embodiment illustrated in FIGS. 1 to 8.

In the modified example illustrated in FIG. 10, the same components as those in the exemplary embodiment illustrated in FIGS. 1 to 8 are given the same reference numerals, and detailed descriptions thereof will be omitted.

In the modified example illustrated in FIG. 10, when the drainage liquid is sent to the oil-water separator 32 from the mixed drainage liquid tank 31, the stirring mechanism 31B such as, for example, a propeller, a screw or an impeller may be provided to stir the drainage liquid within the mixed drainage liquid tank 31. After the drainage liquid within the mixed drainage liquid tank 31 is stirred by the stirring mechanism 31B, the drainage liquid may be sent to the oil-water separator 32 to improve the performance of oil-water separation of DIW and IPA, and the mixed liquid including the first and second fluorine-containing organic solvents. Here, the mixed drainage liquid tank 31 may be a tank with a sealed structure.

In the modified example illustrated in FIG. 10, the covers 31A, 33A, 35A, and 36A may be provided within the mixed drainage liquid tank 31, the buffer tank 33, the first tank 35 and the second tank 36 in which the liquid including the mixed liquid of the first and second fluorine-containing organic solvents is stored. The covers 31A, 33A, 35A, and 36A, which are, for example, resinous, float on the liquid surfaces within the tanks 31, 33, 35, and 36 and have sizes which cover almost the whole liquid surfaces.

The covers 31A, 33A, 35A, and 36A may suppress the mixed liquid of the first and second fluorine-containing organic solvents from being volatilized. In another embodiment, the structure of each of the mixed drainage liquid tank 31, the buffer tank 33, the first tank 35, and the second tank 36 may be constituted by, for example, a bellows-type tank (not illustrated) which flexibly changes according to, for example, the amount of the stored liquid. Accordingly, the space within each of the tanks 31, 33, 35, and 36, in which the mixed liquid is volatilized, is eliminated to suppress the volatilization of the mixed liquid.

The cover may be provided in at least one of the mixed drainage liquid tank 31, the buffer tank 33, the first tank 35 and the second tank 36 described above. Otherwise, at least one of the mixed drainage liquid tank 31, the buffer tank 33, the first tank 35 and the second tank 36 may be a bellows-type tank.

In the modified example illustrated in FIG. 10, the preheater 49A may be provided in the supply line 49 connected the distillation tank 34 to preheat the mixed liquid of the first and second fluorine-containing organic solvents. In this manner, when the preheater 49A is provided, the mixed liquid of the first and second fluorine-containing organic solvents may be heated up to the same temperature as that of the heater 34a of the distillation tank 34 to be supplied to the distillation tank 34. Thus, it is possible to reduce the time required for separating the mixed liquid into the first fluorine-containing organic solvent and the second fluorine-containing organic solvent through heating by the heater 34a in the distillation tank 34.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A separation and regeneration apparatus comprising:
a mixed liquid generating unit configured to generate a mixed liquid which includes a first fluorine-containing organic solvent having a first boiling point, and a second fluorine-containing organic solvent having a second boiling point higher than the first boiling point
a distillation tank including a heater configured to heat the mixed liquid up to a temperature between the first boiling point and the second boiling point, the distillation tank being configured to separate the mixed liquid into the first fluorine-containing organic solvent in a gas state and the second fluorine-containing organic solvent in a liquid state;
a first tank configured to liquefy and store the first fluorine-containing organic solvent in the gas state which is sent from the distillation tank; and
a second tank configured to store the second fluorine-containing organic solvent in the liquid state which is sent from the distillation tank,
wherein the distillation tank separates the mixed liquid into a liquid including the first fluorine-containing organic solvent in a large amount and a liquid including the second fluorine-containing organic solvent in a large amount in a separation ratio corresponding to a mixing ratio of the mixed liquid in the mixed liquid generating unit.

2. The separation and regeneration apparatus of claim 1, further comprising:
a liquid processing unit configured to supply the first fluorine-containing organic solvent, and the second fluorine-containing organic solvent to a processing target object to perform a liquid processing.

3. The separation and regeneration apparatus of claim 2, wherein a buffer tank is provided between the liquid processing unit and the distillation tank to constitute the mixed liquid generating unit.

4. The separation and regeneration apparatus of claim 2, wherein the liquid processing unit constitutes the mixed liquid generating unit.

5. The separation and regeneration apparatus of claim 2, wherein a first supply line is provided between the first tank and the liquid processing unit to supply the first fluorine-containing organic solvent, and a second supply line is provided between the second tank and the liquid processing unit to supply the second fluorine-containing organic solvent.

6. The separation and regeneration apparatus of claim 5, wherein a first concentration meter is provided in the first supply line to measure a concentration of the first fluorine-containing organic solvent, and a second concentration meter is provided in the second supply line to measure a concentration of the second fluorine-containing organic solvent.

7. The separation and regeneration apparatus of claim 1, wherein a first new liquid supply line is provided in the first tank to supply a new first fluorine-containing organic solvent, and a second new liquid supply line is provided in the second tank to supply a new second fluorine-containing organic solvent.

8. The separation and regeneration apparatus of claim 1, wherein the mixed liquid generating unit is constituted by a mixed drainage liquid tank, and
a stirring mechanism is provided in the mixed drainage liquid tank to stir the mixed liquid.

9. The separation and regeneration apparatus of claim 1, wherein the mixed liquid generating unit is constituted by a mixed drainage liquid tank, and
a cover is provided in at least one tank of the mixed drainage liquid tank, the first tank, and the second tank, the cover floating on a liquid surface to cover the liquid surface.

10. The separation and regeneration apparatus of claim 1, wherein a preheater is provided between the mixed liquid generating unit and the distillation tank to preheat the mixed liquid.

11. A substrate processing apparatus comprising:
a liquid processing unit configured to supply a first fluorine-containing organic solvent having a first boiling point and a second fluorine-containing organic solvent having a second boiling point higher than the first boiling point to a processing target object to perform a liquid processing;
a supercritical processing unit configured to bring a liquid of fluorine-containing organic solvent attached to the processing target object after the liquid processing into contact with a supercritical fluid of a fluorine-containing organic solvent to remove the liquid; and
a substrate conveyance unit configured to convey the processing target object which has been subjected to the liquid processing in the liquid processing unit to the supercritical processing unit,
wherein the separation and regeneration apparatus of claim 1 is included in the liquid processing unit.
